(19) United States
(12) Patent Application Publication
(10) Pub. No.: US 2011/0095381 A1
(43) Pub. Date: Apr. 28, 2011

(54) Gate structure and method for making same

(76) Inventors: Markus Müller, Grenoble (FR); Benoît Froment, Grenoble (FR)

(21) Appl. No.: 11/664,853

(22) PCT Filed: Oct. 5, 2005
(86) PCT No.: PCT/FR05/50812

§ 371 Date: May 21, 2009

(30) Foreign Application Priority Data
Oct. 5, 2004 (FR) 0452272

(51) Int. Cl. H01L 29/49; H01L 21/336; H01L 21/28

(52) U.S. Cl. 257/413; 438/197; 438/592; 257/E29.161; 257/E21.409; 257/E21.19

(57) ABSTRACT

A MOS transistor having its gate successively comprising an insulating layer, a metal silicide layer, a layer of a conductive encapsulation material, and a polysilicon layer.

### PRIORITY CLAIM

[1] This application claims priority to PCT Application No. PCT/FR2005/050812 filed Oct. 5, 2005, which claims priority to French Patent Application No. 04/52272 filed Oct. 5, 2004, which are incorporated herein by reference.

### TECHNICAL FIELD

The present invention generally relates to the field of MOS structures made in the form of integrated circuits, and to their manufacturing methods. It more specifically relates to the gate structure of a MOS transistor and its manufacturing method.

### BACKGROUND

MOS transistors generally have a polysilicon gate. FIG. 1 is a simplified cross-section view of such a transistor. In a semiconductor substrate 1, for example, made of silicon, a transistor 2 is formed between shallow trench insulation areas 3 (STI), for example, silicon oxide. Transistor 2 comprises a polysilicon gate 4, formed on a gate insulator 5 that may be, as an example, silicon oxide or a material with a strong dielectric constant such as hafnium oxide. Lightly-doped drain areas (LDD) 8 and 9 are then formed, for example, by ion implantation. On the sides of gate 5 are formed spacers 10 made of an insulating material, for example, oxide or silicon nitride. Source and drain areas 11 and 12 are formed, for example, by ion implantation. On source and drain areas 11 and 12 as well as on the top of gate 4 are simultaneously formed metal silicide contacts 13, 14, and 16, for example, silicon nitride.

The gate structure is thus formed of a stacking of an insulating layer, of a polysilicon layer doped by ion implantation, and of a metal silicide layer.

Various authors have suggested to replace the polysilicon gates topped with metal silicide with gates fully made of silicide for two main reasons. The first reason is to overcome the polysilicon depletion phenomenon. Indeed, the electrons of gate 4 are pushed back with respect to gate oxide 5. A depletion area is thus created above oxide 5 with fewer carriers. As an example, this area may have a 0.4-nm thickness. A stray capacitance is thus generated in series with the capacitance of gate oxide 5, the capacitance of the assembly becoming lower. Since the operating current of the transistor is proportional to this capacitance, it will thus be lower. The second reason is to decrease the gate resistance.

FIG. 2 is a simplified cross-section view illustrating a possibility for forming a fully silicided gate. It is started from a structure such as that in FIG. 1 and, instead of performing an only partial silicidation of gate 4, the processing time is lengthened so that gate 20 is completely silicided. The disadvantage of such as method in a conventional technology is that if the silicidation is carried on so that it extends across the entire thickness of polysilicon gate 20, a same silicidation thickness will be present at level 21 and 22 of the source and drain regions. This poses many problems. Indeed, the silicidation depth must be smaller than the depth of source and drain areas 11 and 12 (see FIG. 1) to ensure a proper operation of the MOS transistor. This is in practice not possible if MOS transistors of very small dimensions are desired to be kept, which is a constant object of integrated circuit manufacturing.

To solve this problem, various methods have been provided, among which that provided in the article entitled “Demonstration of Fully Ni-Silicided Metal Gates on HfO2 based high-k gate dielectrics as a candidate for low power applications” by Anil et al., published in the 2004 Symposium on VLSI Technology, which is incorporated by reference. FIGS. 3A to 3G illustrate this method.

At the step illustrated in FIG. 3A, after having formed insulation areas 3 in substrate 1, a silicon oxide insulating layer 31, a polysilicon layer 32, and a hard silicon oxide mask layer 33 are successively formed.

At the step illustrated in FIG. 3B, after having performed a photolithography, the three layers 31, 32, and 33 are successively etched. A gate pattern 34 formed of a stacking of a gate oxide 36, of an insulated gate 37, and of a hard mask 38 is thus obtained.

At the step illustrated in FIG. 3C, the implantations of LDD areas 8 and 9 are performed by using gate pattern 34 as a mask, after which spacers 10 are formed before doping source and drain areas 11 and 12 by using the gate pattern as a mask.

At the step illustrated in FIG. 3D, the metal silicidation of source and drain areas 11 and 12 is performed to obtain contact areas 13 and 14.

At the step illustrated in FIG. 3E, hard mask 38 is removed before depositing a thick oxide layer 40.

At the step illustrated in FIG. 3F, layer 40 is planarized by chem./mech polishing CMP. Layer 40 is etched until gate 37 is exposed. A nickel layer 41 is deposited afterwards before performing an anneal for a sufficient time to fully silicide polysilicon 37.

FIG. 3G is a simplified cross-section view of the resulting MOS transistor, having a fully silicided gate 20. The gate structure is thus formed of a stacking of an insulating layer and of a metal silicide layer. However, this manufacturing process is difficult to implement due to the large number of steps that it requires and is critical as concerns the uniformity of the upper gate surface, due to the presence of a CMP planarization step.

### SUMMARY

An embodiment of the present invention is a novel structure of a MOS transistor with a fully silicided gate.

Another embodiment of the present invention is a method for manufacturing a MOS transistor with a fully silicided gate, which is easy to implement.

Another embodiment of the present invention is a manufacturing method which is compatible with a standard CMOS method.

Yet another embodiment of the present invention is a MOS transistor gate successively comprising an insulating layer, a metal silicide layer, a layer of a conductive encapsulation material, and a polysilicon layer.

According to an embodiment of the present invention, the metal silicide layer is a nickel silicide layer.

According to an embodiment of the present invention, the encapsulation layer is selected from the group comprising titanium nitride and tantalum nitride.

According to an embodiment of the present invention, the thickness of the metal silicide layer is smaller than 25 nm.

According to an embodiment of the present invention, the thickness of the encapsulation layer is smaller than 20 nm.

According to an embodiment of the present invention, the gate further comprises a second layer of a metal silicide at the upper portion of the polysilicon layer.

An embodiment of the present invention also provides a method for manufacturing a MOS transistor gate comprising the successive steps of forming an insulating gate insulator layer; forming a thin polysilicon layer; implanting an N- or P-type dopant in the polysilicon layer; turning the polysilicon into a metal silicide; forming a layer of a conductive encapsulation material; and forming a polysilicon layer so that the total gate thickness has the usual thickness of a gate in a given MOS transistor manufacturing technology.

### BRIEF DESCRIPTION OF THE DRAWINGS

Features and advantages of the present invention will be discussed in detail in the following non-limiting description of specific embodiments in connection with the accompanying drawings.

FIG. 1, previously described, is a simplified cross-section view of a conventional transistor comprising a polysilicon gate.

FIG. 2, previously described, is a simplified cross-section view of a conventional transistor comprising a metal silicide gate.

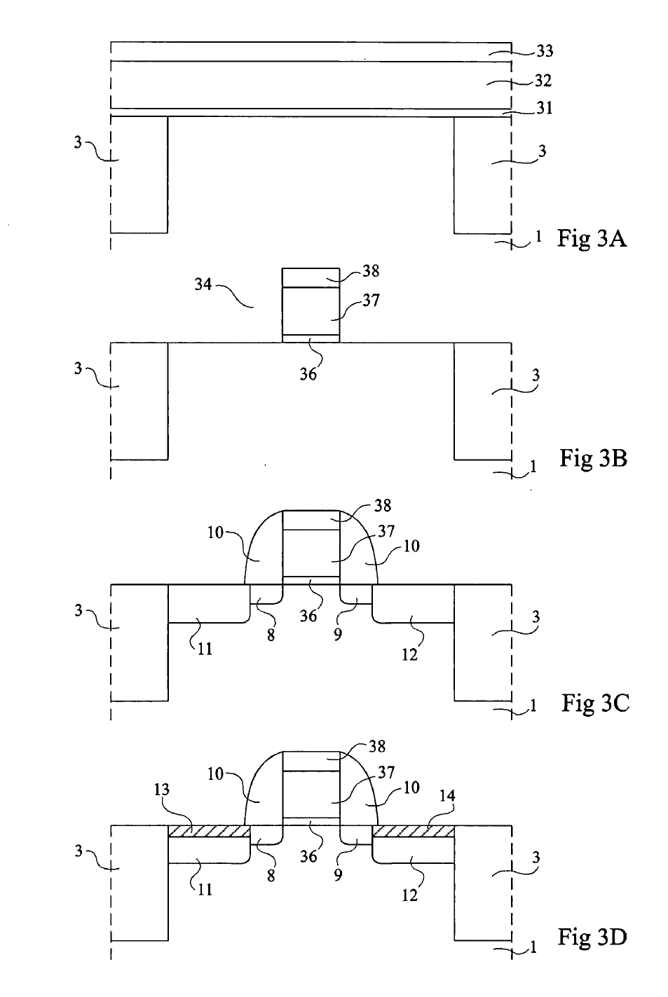

FIGS. 3A to 3G, previously described, illustrates a conventional manufacturing method providing a fully silicided gate.

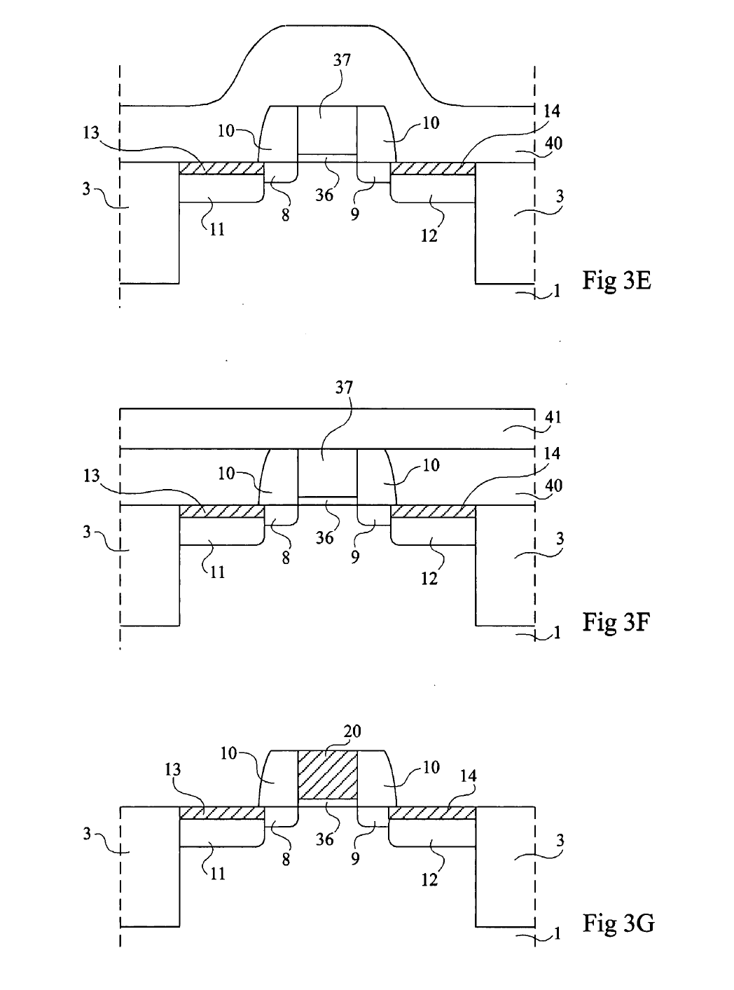

FIGS. 4A to 4D illustrate a method for manufacturing a MOS transistor gate according to an embodiment of the present invention.

### DETAILED DESCRIPTION

For clarity, same elements have been designated with same reference numerals in the different drawings and, further, as usual in the representation of integrated circuits, the various drawings are not to scale.

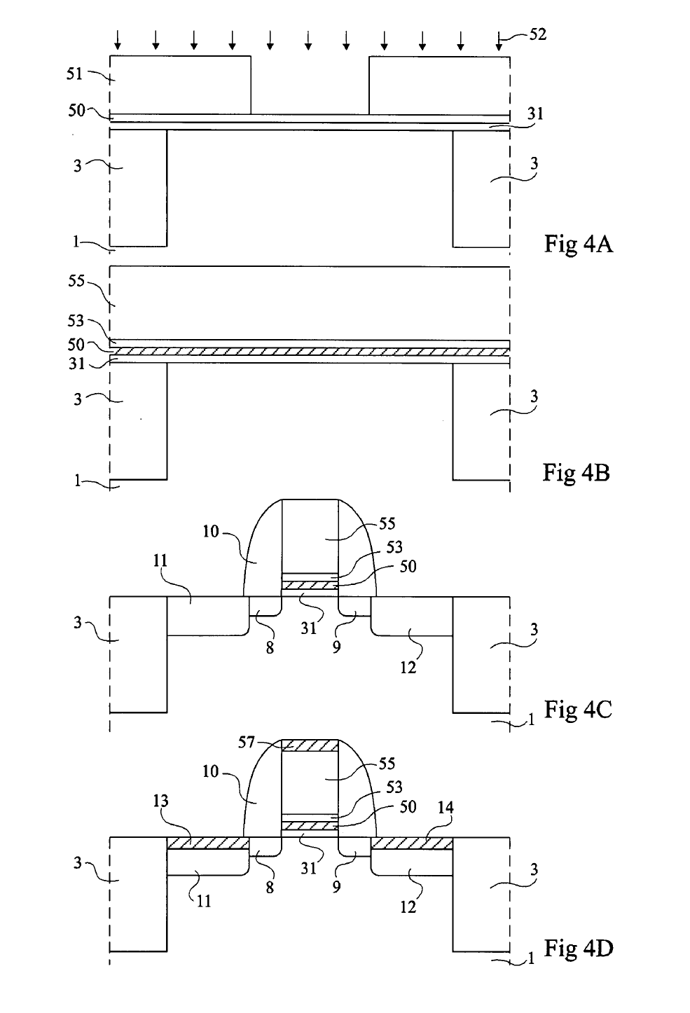

An embodiment of the present invention will be described in relation with FIGS. 4A to 4D in the context of a specific method for obtaining the desired structure, it being understood that this method is an example only and that those skilled in the art may devise other methods enabling achieving this embodiment of the present invention and alternative embodiments according to the present invention.

As illustrated in FIG. 4A, it is started from a solid silicon substrate 1 or from any other conventional integrated circuit substrate. An active region delimited by insulation areas 3 is defined in substrate 1. On this structure, a thin insulating layer 31 intended to be used as a gate oxide is formed. Then, a thin polysilicon layer 50 is deposited. Conventionally, layer 31 intended to be used as a gate oxide layer will have a thickness on the order of a few nanometers. Polysilicon layer 46 will for example have a thickness on the order of from 10 to 30 nm. The structure is covered with a mask 51 which comprises an opening that extends beyond the location where the gate is subsequently desired to be formed. An implantation of an N or P dopant represented with arrows 52 is performed. The object of this implantation will be discussed hereafter.

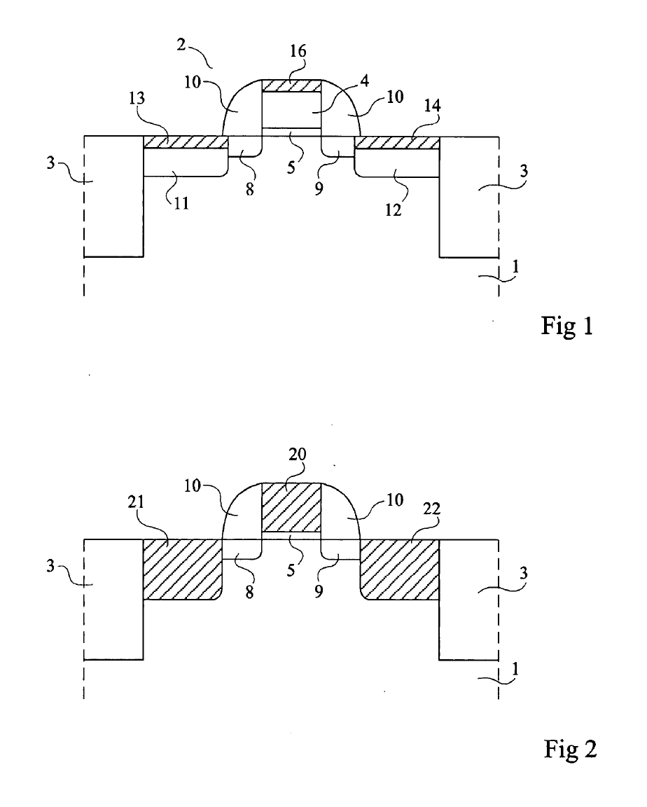

The intermediary structure illustrated in FIG. 4B results from a succession of steps during which mask 51 is removed and thin polysilicon layer 50 is silicided by any known means, for example, by deposition of a metal layer and anneal. The metal for example is nickel or cobalt which has the property of not allowing conventional silicon-doping dopants such as As, B, and P to diffuse therein. A layer 53 of a conductive encapsulation material which does not react with polysilicon, for example, TiN or TaN, is then deposited over a sufficient thickness to ensure the desired encapsulation function. After this, a polysilicon layer 55 is deposited. The thickness of polysilicon layer 55 is selected to that the total thickness of layers 50, 53, 55 corresponds to the currently used thickness of a gate in a conventional MOS transistor manufacturing technology such as that described in relation with FIG. 1. Thus, after the previously-described initial steps, the manufacturing of a MOS transistor can be carried on without modifying the usual manufacturing technologies of such transistors such as described in relation with FIG. 1.

At the step illustrated in FIG. 4C, gate stacking 31, 50, 53, 55 is etched to form a gate having the desired usual configuration. After this, LDD areas 8 and 9 are implanted, lateral spacers 10 are formed around the gate, and source and drain areas 11 and 12 are implanted. It should incidentally be noted that, in the implantation of source and drain areas 11 and 12, upper polysilicon portion 55 of the gate will have been implanted, and thus made strongly-conductive.

As illustrated in FIG. 4D, a conventional silicidation step is performed to silicide the upper portion of source and drain areas 11 and 12 and obtain silicided regions 13 and 14. A silicided region 57 is obtained at the same time on the upper portion of the gate stacking.

An advantage of providing conductive encapsulation layer 53, which is also used as a diffusion barrier, should be noted. Indeed, in anneal steps linked to the forming of source and drain regions 11 and 12 and silicided regions 13, 14, and 57, the device is brought up to temperatures on the order of 1,000° C. However, nickel silicide (NiSi) only remains stable up to approximately 750° C. Beyond this temperature, it tends to turn into NiSi2, then melts. The dopants would then be at risk to diffuse by drive-in, or the work function of the lower silicided portion might modify the transistor operation. The encapsulation layer overcomes this disadvantage.

It should be reminded that at the step illustrated in relation with FIG. 4A, an ion implantation of a dopant has been performed in polysilicon layer 50 before its silicidation. The selected dopant is non or only a little soluble into silicide. This step results in that, at the interface between silicide layer 50 and gate oxide 31, there remain N- or P-type dopants which modify as desired the gate work function for an optimal operation of an N-channel or P-channel transistor.

It should be noted that the gate according to this embodiment of the present invention is not fully silicided given that there remains a non-silicided polysilicon region 55. In fact, this has no incidence upon the transistor gate according to this embodiment of the present invention since what matters is for a layer having a metallic behavior to be present in the immediate vicinity of gate insulator 31.

As an example of dimensions, it should be noted that an embodiment of the present invention adapts to any conventional forming of a MOS transistor. Generally, each specific MOS transistor manufacturing technology especially characterizes by the minimum gate length, and by the thickness of this gate to obtain spacers with satisfactory dimensions and a sufficient protection of the area located under the gate with respect to the implantations performed to form the source and drain areas. In the case of a technology in which the gate width is on the order of 0.3 μm, the following dimensions may be selected:

thickness of gate oxide layer 31: from 1 to 5 nm,

thickness of silicide layer 50: from 10 to 30 nm,

thickness of nickel encapsulation layer 53: 10 nm,

thickness of polysilicon layer 55: from 60 to 120 nm.

The transistor of FIG. 4D may be incorporated in an integrated circuit (IC), which may be incorporated in an electronic system such as a computer system. In the electronic system, the IC may be coupled to another IC such as a controller.

From the foregoing it will be appreciated that, although specific embodiments of the invention have been described herein for purposes of illustration, various modifications may be made without deviating from the spirit and scope of the invention.

1. A MOS transistor gate successively comprising an insulating layer, a metal silicide layer, a layer of a conductive encapsulation material, and a polysilicon layer.

2. The gate of claim 1, wherein the metal silicide layer comprises a nickel silicide layer.

3. The gate of claim 1, wherein the encapsulation layer is selected from the group comprising titanium nitride and tantalum nitride.

4. The gate of claim 1, wherein the thickness of the metal silicide layer is smaller than 25 nm.

5. The gate of claim 1, wherein the thickness of the encapsulation layer is smaller than 20 nm.

6. The gate of claim 1, further comprising a second layer of a metal silicide at the upper portion of the polysilicon layer.

7. A MOS transistor having the gate of claim 1.

8. A method for manufacturing a MOS transistor gate comprising the successive steps of:
forming an insulating gate insulator layer;
forming a thin polysilicon layer;
implanting an N- or P-type dopant in the polysilicon layer;
turning the polysilicon into a metal silicide;
forming a layer of a conductive encapsulation material; and
forming a polysilicon layer so that the total gate thickness has the usual thickness of a gate in a given MOS transistor manufacturing technology.

9. The method of claim 8, further comprising the steps of:
forming source and drain areas of the MOS transistors, and
siliciding said source and drain areas.

10. The method of claim 8, wherein the metal silicide comprises nickel silicide.

11. The method of claim 8, wherein the encapsulation layer is selected from the group comprising titanium nitride and tantalum nitride.

12. A transistor, comprising:
a body region disposed in a substrate; and
a gate structure, comprising,
an insulator disposed on the substrate over the body region,
a first silicide layer disposed on the insulator,
a conductive layer disposed on the first silicide layer, and
a second silicide layer disposed on the conductive layer.

13. The transistor of claim 12 wherein the first silicide layer comprises polysilicon and nickel.

14. The transistor of claim 12 wherein the first silicide layer comprises polysilicon and cobalt.

15. The transistor of claim 12 wherein the conductive layer comprises polysilicon.

16. The transistor of claim 12 wherein the conductive layer comprises titanium nitride.

17. The transistor of claim 12 wherein the conductive layer comprises tantalum nitride.

18. The transistor of claim 12 wherein the conductive layer comprises:
an encapsulation layer disposed on the first silicide layer and comprising a material that does not react with polysilicon; and
a polysilicon layer disposed on the encapsulation layer.

19. The transistor of claim 12 wherein the conductive layer comprises:
a diffusion barrier disposed on the first silicide layer; and
a polysilicon layer disposed on the diffusion barrier.

20. An integrated circuit, comprising:
a transistor, comprising,
a body region disposed in a substrate; and
a gate structure, comprising,
an insulator disposed on the substrate over the body region,
a first silicide layer disposed on the insulator,
a conductive layer disposed on the first silicide layer, and
a second silicide layer disposed on the conductive layer.

21. An electronic system, comprising:
integrated circuit, comprising,
a transistor, comprising,
a body region disposed in a substrate; and
a gate structure, comprising,
an insulator disposed on the substrate over the body region,
a first silicide layer disposed on the insulator,
a conductive layer disposed on the first silicide layer, and
a second silicide layer disposed on the conductive layer.

22. A method, comprising:
forming a gate insulator on a substrate;
forming a first silicide layer on the insulator;
forming a conductive layer on the first silicide layer; and
forming a second silicide layer on the conductive layer.

23. The method of claim 22, further comprising doping the first silicide layer before forming the conductive layer.

24. The method of claim 22, further comprising doping the conductive layer before forming the second silicide layer.

25. The method of claim 22, further comprising forming third and fourth silicide layers on source and drain regions, respectively, while forming the second silicide layer.
